(19) United States
(12) Patent Application Publication
(10) Pub. No.: US 2024/0305253 A1
(43) Pub. Date: Sep. 12, 2024

(54) ELECTRONIC DEVICE

(71) Applicant: Hexawave, Inc., Hsinchu (TW)

(72) Inventors: Yung-Pin LIU, Hsinchu (TW); Ming-Yan TSAI, Hsinchu (TW)

(21) Appl. No.: 18/594,481

(22) Filed: Mar. 4, 2024

Related U.S. Application Data
(60) Provisional application No. 63/488,539, filed on Mar. 6, 2023.

(30) Foreign Application Priority Data
Sep. 15, 2023 (TW) 112135238

(51) Int. Cl. H03F 3/21

(52) U.S. Cl. CPC H03F 3/21

(57) ABSTRACT

An electronic device includes an input end, a power amplifier, a voltage dividing circuit, and a driving circuit. The input end receives an input signal. The power amplifier is electrically connected between the power voltage and the ground voltage and includes a first control end. The voltage dividing circuit divides the input signal and outputs a divided voltage signal. The driving circuit includes a second control end. The driving circuit is electrically connected to the voltage dividing circuit through the second control end. The driving circuit is electrically connected to the first control end of the power amplifier. The driving circuit is electrically connected to the input end through a bus to receive the input signal. The driving circuit outputs the input signal to the power amplifier according to the voltage of the divided voltage signal to drive the power amplifier.

### CROSS REFERENCE TO RELATED APPLICATIONS

This application claims priority of U.S. Provisional Application No. 63/488,539, filed on Mar. 6, 2023, and Taiwan Patent Application No. 112135238, filed on Sep. 15, 2023, the entirety of which is incorporated by reference herein.

### FIELD OF THE INVENTION

The present application relates to an electronic device, and, in particular, to a power amplifier with controllable threshold voltages.

### DESCRIPTION OF THE RELATED ART

The threshold voltage of currently commercialized p-type gallium nitride semiconductor power devices (the normally-off type) is around 1V. However, due to the low threshold voltage of p-type gallium nitride semiconductor power devices, it often happens that other signals interfere with the gate of a p-type gallium nitride semiconductor power device, causing the p-type gallium nitride semiconductor power device turn on by mistake. Therefore, how to adjust the threshold voltage of semiconductor power devices to match the system operating voltage has become an important issue.

### BRIEF SUMMARY OF THE INVENTION

In order to solve the above problems, an embodiment of the present application provides an electronic device. The electronic device includes an input end, a power amplifier, a voltage dividing circuit, and a driving circuit. The input end receives an input signal. The power amplifier is electrically connected between a power voltage and a ground voltage and includes a first control end. The voltage dividing circuit divides the input signal and outputs a divided voltage signal. The driving circuit includes a second control end, is electrically connected to the voltage dividing circuit through the second control end, and is electrically connected to the first control end of the power amplifier. The driving circuit is electrically connected to the input end through a bus to receive the input signal. The driving circuit outputs the input signal to the power amplifier according to the voltage of the divided voltage signal to drive the power amplifier.

According to the electronic device described above, the voltage dividing circuit comprises a first resistor and a second resistor. The first resistor is electrically connected between the second resistor and the input end. The second resistor is electrically connected between the first resistor and the ground voltage.

According to the electronic device described above, the driving circuit includes a first switch element. The first switch element includes a first end, a second end, and a control end. The first end is electrically connected to the input end. The second end is electrically connected to the first control end of the power amplifier. The control end is electrically connected between the first resistor and the second resistor.

According to the electronic device described above, the driving circuit includes a first switch element and a second switch element. The first switch element includes a first end, a second end, and a control end. The second switch element includes a first end, a second end, and a control end.

According to the electronic device described above, the first end of the first switch element is electrically connected to the input end. The second end of the first switch element is electrically connected to the control end of the second switch element. The control end of the first switch element is electrically connected between the first transistor and the second transistor.

According to the electronic device described above, the first end of the second switch element is electrically connected to the input end. The second end of the second switch element is electrically connected to the first control end of the power amplifier.

According to the electronic device described above, when the voltage of the divided voltage signal is higher than a threshold voltage of the first switch element, the first switch element outputs the input signal to the power amplifier through its second end.

According to the electronic device described above, when the voltage of the divided voltage signal is higher than a threshold voltage of the first switch element, the first switch element outputs the input signal to the second switch element through its second end, so that the second switch element outputs the input signal to the power amplifier through its second end.

According to the electronic device described above, the power amplifier includes a switch element. The switch element has a threshold voltage. The voltage of the divided voltage signal is higher than the threshold voltage.

According to the electronic device described above, the driving circuit includes multiple switch elements. The switch elements are electrically connected in series with each other. The first switch element is electrically connected to the power amplifier, and the last switch element is electrically connected to the voltage dividing circuit.

### BRIEF DESCRIPTION OF THE DRAWINGS

The present application can be more fully understood by reading the subsequent detailed description and examples with references made to the accompanying drawings, wherein:

FIG. 1 is a schematic diagram of an electronic device 100 in accordance with some embodiments of the present application.

FIG. 2 is a detail schematic diagram of the electronic device 100 in FIG. 1 in accordance with some embodiments of the present application.

### DETAILED DESCRIPTION OF THE INVENTION

In order to make the above purposes, features, and advantages of some embodiments of the present application more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” and/or “include” used in the present application are used to indicate the existence of specific technical features, values, method steps, operations, units and/or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present application. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, “third”, “fourth”, “fifth”, and “sixth” are used to describe components. They are not used to indicate the priority order of or advance relationship, but only to distinguish components with the same name.

It should be noted that the technical features in different embodiments described in the following can be replaced, recombined, or mixed with one another to constitute another embodiment without departing from the spirit of the present application.

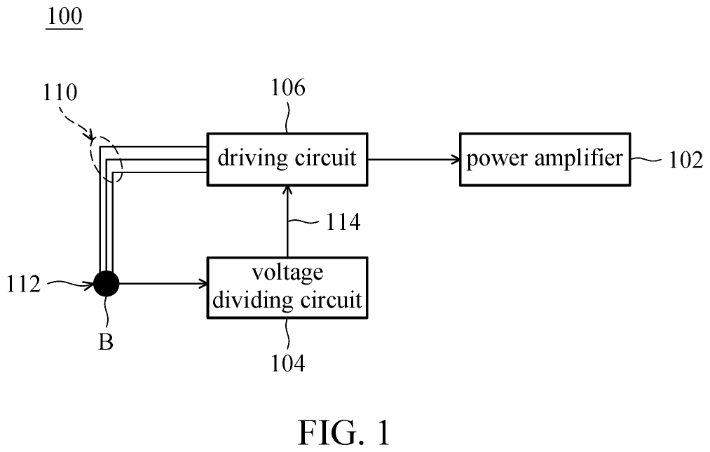

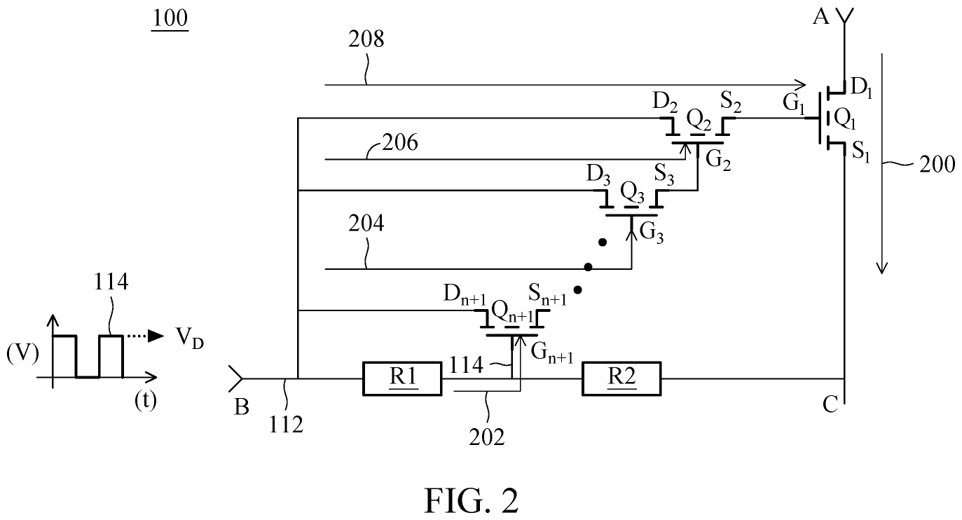

FIG. 1 is a schematic diagram of an electronic device 100 in accordance with some embodiments of the present application. As shown in FIG. 1, the electronic device 100 includes an input end B, a power amplifier 102, a voltage dividing circuit 104, and a driving circuit 106. In some embodiments, the input end B receives an input signal 112. In some embodiments, the input signal 112s, for example, comes from a radio transceiver (not shown), but the present application is not limited thereto. In other words, the input end B is electrically connected to a radio transceiver, for example, but the present application is not limited thereto. In some embodiments, the power amplifier 102 is electrically connected to a power voltage (such as a power voltage A in FIG. 2) and a ground voltage (such as a ground voltage C in FIG. 2). The power amplifier 102 includes a control end to receive the input signal 112 from the driving circuit 106, and amplifies the input signal 112 to generate an output signal (not shown). In some embodiments, the power amplifier 102 further includes an output end to send the output signal to circuit components in the next stage. In some embodiments, the circuit components in the next stage may, for example, be an antenna or a filter, but the present application is not limited thereto.

The voltage dividing circuit 104 is electrically connected to the input end B, divides the input signal 112 from the input end B, and outputs a divided voltage signal 114 to the driving circuit 106. In some embodiments, the voltage of the divided voltage signal 114 is the voltage used to start the power amplifier 102, but the present application is not limited thereto. In some embodiments, the driving circuit 106 includes a control end. The driving circuit 106 is electrically connected to the voltage dividing circuit 104 through its control end. The driving circuit 106 is electrically connected to the control end of the power amplifier 102. In some embodiments, the driving circuit 106 is electrically connected to the input end B through a bus 110 to receive the input signal 112. In some embodiments, the bus 110 includes at least one connection line. The number of connection lines included in the bus 110 is equal to the number of switch elements included in the driving circuit 106. In some embodiments, the driving circuit 106 outputs the input signal 112 to the power amplifier 102 according to the voltage of the divided voltage signal 114 to drive the power amplifier 102, so that the input signal 112 is amplified. In some embodiments, the electronic device 100 may be, for example, a radio frequency front-end circuit in a mobile device, but the present application is not limited thereto.

FIG. 2 is a detail schematic diagram of the electronic device 100 in FIG. 1 in accordance with some embodiments of the present application. Please refer to FIG. 1 and FIG. 2 at the same time. As shown in FIG. 2, the power amplifier 102 includes a switch element Q1. The switch element Q1 includes a first end D₁, a second end S₁, and a control end G₁. In some embodiments, the first end D₁ may be, for example, a drain of the switch element Q1. The second end S₁ may be, for example, a source of the switch element Q1. The control end G₁ may be, for example, a gate of the switch element Q1. The first end D₁ of the switch element Q1 is electrically connected to the power voltage A. The second end S₁ of the switch element Q1 is electrically connected to the ground voltage C. The control end G₁ of the switch element Q1 is electrically connected to the second end S₂ of the switch element Q2 included in the driving circuit 106. In some embodiments, the voltage dividing circuit 104 includes a resistor R1 and a resistor R2. The resistor R1 is electrically connected between the input end B and the resistor R2. The resistor R2 is electrically connected between the resistor R1 and the ground voltage C. According to the voltage division theorem, the input signal 112 and the divided voltage signal 114 satisfy the following relationship.

$$divided voltage signal 114 = \frac{R 2}{R 1 + R 2} \times input signal 112$$

R1 in the above equation is a resistance value of the resistor R1, and R2 is the resistance value of the resistor R2.

In some embodiments, the switch element Q1 has a threshold voltage (Vth). The voltage of the divided voltage signal 114 (for example, the voltage VD, FIG. 2 shows the waveform of the divided voltage signal 114, the horizontal axis (t) is time and the vertical axis (V) is voltage) is higher than the threshold voltage of the switch element Q1. In some embodiments, the switch element Q1 may be, for example, a Metal-Oxide-Semiconductor Field-Effect Transistor (MOSFET), but the present application is not limited thereto.

In some embodiments of FIG. 2, the driving circuit 106 includes n switch elements, for example, a switch element Q2, a switch element Q3, . . . , and a switch element Qn+1, wherein n is a positive integer. In other words, the driving circuit 106 includes at least one switch element. Switch elements are connected in series with each other. The first switch element (for example, switch element Q2) is electrically connected to the switch element Q1 (that is, the power amplifier 102), and the last switch element (for example, switch element Qn+1) is electrically connected between the resistor R1 and the resistor R2 (i.e., the voltage dividing circuit 104). In some embodiments, the switch element Qn+1 includes a first end Dₙ₊₁, a second end Sₙ₊₁, and a control end Gₙ₊₁.

In detail, in some embodiments of FIG. 2, when n=1, the driving circuit 106 includes a switch element Q2. The switch element Q2 includes a first end D₂, a second end S₂, and a control end G₂. In some embodiments, the first end D₂ may be, for example, a drain of the switch element Q2. The second end S₂ may be, for example, a source of the switch element Q2. The control end G₂ may be, for example, a gate of the switch element Q2. The first end D₂ of the switch element Q2 is electrically connected to the input end B. The second end S₂ of the switch element Q2 is electrically connected to the control end G₁ of the switch element Q1. The control end G₂ of the switch element Q2 is electrically connected between the resistor R1 and the resistor R2. In some embodiments, the switch element Q2 has a threshold voltage.

In some embodiments, the input end B receives the input signal 112. The input signal 112 is divided by the resistor R1 to generate the divided voltage signal 114. If the voltage of the divided voltage signal 114 is not higher than the threshold voltage of the switch element Q2, the switch element Q2 is turned off, and the input signal 112 cannot be sent to the control end G₁ of the switch element Q1. Therefore, the switch element Q1 is turned off. If the voltage of the divided voltage signal 114 (for example, the voltage VD) is higher than the threshold voltage of the switch element Q2, a current 202 flows from the resistor R1 to the control end G₂ of the switch element Q2, so that the accumulated charge at the control end G₂ of the switch element Q2 is more than or equal to a total gate charge (Qg) of the switch element Q2. At this time, the switch element Q2 is turned on. When the switch element Q2 is turned on, the input signal 112 may be sent to the control end G₁ of the switch element Q1 through the first end D₂ and the second end S₂ of the switch element Q2.

When the input signal 112 is sent to the control end G₁ of the switch element Q1, a current 208 flows from the input end B to the control end G₁ of the switch element Q1, so that the accumulated charge at the control end G₁ of the switch element Q1 is more than or equal to the total gate charge (Qg) of the switch element Q1. At this time, the switch element Q1 is turned on, and a current 200 flows from the power voltage A through the first end D₁ and the second end S₁ of the switch element Q1, and finally flows to the ground voltage C, so that the input signal 112 is amplified by the switch element Q1.

In detail, in some embodiments of FIG. 2, when n=2, the driving circuit 106 includes a switch element Q2 and a switch element Q3. The switch element Q2 includes a first end D₂, a second end S₂, and a control end G₂. The switch element Q3 includes a first end D₃, a second end S₃, and a control end G₃. In some embodiments, the first end D₂ may be, for example, a drain of the switch element Q2. The second end S₂ may be, for example, a source of the switch element Q2. The control end G₂ may be, for example, a gate of the switch element Q2. The first end D₃ may be, for example, a drain of the switch element Q3. The second end S₃ may be, for example, a source of the switch element Q3. The control end G₃ may be, for example, a gate of the switch element Q3. The first end D₂ of the switch element Q2 is electrically connected to the input end B. The second end S₂ of the switch element Q2 is electrically connected to the control end G₁ of the switch element Q1. The control end G₂ of the switch element Q2 is electrically connected to the second end S₃ of the switch element Q3. The first end D₃ of the switch element Q3 is electrically connected to the input end B. The control end G₃ of the switch element Q3 is electrically connected between the resistor R1 and the resistor R2. In some embodiments, the switch elements Q2 and Q3 have a threshold voltage respectively.

In some embodiments, the input end B receives the input signal 112. The input signal 112 is divided by the resistor R1 to generate the divided voltage signal 114. If the voltage of the divided voltage signal 114 is not higher than the threshold voltage of the switch element Q3, the switch element Q3 is turned off, and the input signal 112 cannot be sent to the control end G₂ of the switch element Q2. Therefore, the switch element Q2 is turned off. The input signal 112 cannot be sent to the control end G₁ of the switch element Q1. Therefore, the switch element Q1 is turned off.

If the voltage of the divided voltage signal 114 (for example, the voltage VD) is higher than the threshold voltage of the switch element Q3, a current 202 flows from the resistor R1 to the control end G₃ of the switch element Q3, so that the accumulated charge at the control end G₃ of the switch element Q3 is more than or equal to a total gate charge (Qg) of the switch element Q3. At this time, the switch element Q3 is turned on. When the switch element Q3 is turned on, the input signal 112 may be sent to the control end G₂ of the switch element Q2 through the first end D₃ and the second end S₃ of the switch element Q3. When the input signal 112 is sent to the control end G₂ of the switch element Q2, a current 206 flows from the input end B to the control end G₂ of the switch element Q2, so that the accumulated charge at the control end G₂ of the switch element Q2 is more than or equal to a total gate charge (Qg) of the switch element Q2. At this time, the switch element Q2 is turned on. When the switch element Q2 is turned on, the input signal 112 may be sent to the control end G₁ of the switch element Q1 through the first end D₂ and the second end S₂ of the switch element Q2.

When the input signal 112 is sent to the control end G₁ of the switch element Q1, a current 208 flows from the input end B to the control end G₁ of the switch element Q1, so that the accumulated charge at the control end G₁ of the switch element Q1 is more than or equal to a total gate charge (Qg) of the switch element Q1. At this time, the switch element Q1 is turned on, the current 200 flows from the power voltage A through the first end D₁ and the second end S₁ of the switch element Q1, and finally flows to the ground voltage C, so that the input signal 112 is amplified by the switch element Q1.

In detail, in some embodiments of FIG. 2, when n=3, the driving circuit 106 includes a switch element Q2, a switch element Q3, and a switch element Q4. The switch element Q2 includes a first end D₂, a second end S₂, and a control end G₂. The switch element Q3 includes a first end D₃, a second end S₃, and a control end G₃. The switch element Q4 includes a first end D₄, a second end S₄, and a control end G₄. In some embodiments, the first end D₂ may be, for example, a drain of the switch element Q2. The second end S₂ may be, for example, a source of the switch element Q2. The control end G₂ may be, for example, a gate of the switch element Q2. The first end D₃ may be, for example, a drain of the switch element Q3. The second end S₃ may be, for example, a source of the switch element Q3. The control end G₃ may be, for example, a gate of the switch element Q3. The first end D₄ may be, for example, a drain of the switch element Q4. The second end S₄ may be, for example, a source of the switch element Q4. The control end G₄ may be, for example, a gate of the switch element Q4.

The first end D₂ of the switch element Q2 is electrically connected to the input end B. The second end S₂ of the switch element Q2 is electrically connected to the second end S₃ of the switch element Q3. The first end D₃ of the switch element Q3 is electrically connected to the input end B. The control end G₃ of the switch element Q3 is electrically connected to the second end S₄ of the switch element Q4. The first end D₄ of the switch element Q4 is electrically connected to the input end B. The control end G₄ of the switch element Q4 is electrically connected between the resistor R1 and the resistor R2. In some embodiments, the switch elements Q2, Q3, and Q4 have a threshold voltage respectively.

In some embodiments, the input end B receives the input signal 112. The input signal 112 is divided by the resistor R1 to generate the divided voltage signal 114. If the voltage of the divided voltage signal 114 is not higher than the threshold voltage of the switch element Q4, the switch element Q4 is turned off, and the input signal 112 cannot be sent to the control end G₃ of the switch element Q3. Therefore, the switch element Q3 is turned off. When the switch element Q3 is turned off, the input signal 112 cannot be sent to the control end G₂ of the switch element Q2. Therefore, the switch element Q2 is turned off. When the switch element Q2 is turned off, the input signal 112 cannot be sent to the control end G₁ of the switch element Q1. Therefore, the switch element Q1 is also turned off.

If the voltage of the divided voltage signal 114 (for example, the voltage VD) is higher than the threshold voltage of the switch element Q4, a current 202 flows from the resistor R1 to the control end G₄ of the switch element Q4, so that the accumulated charge at the control end G₄ of the switch element Q4 is more than or equal to a total gate charge (Qg) of the switch element Q4. At this time, the switch element Q4 is turned on, the input signal 112 may be sent to the control end G₃ of the switch element Q3 through the first end D₄ and the second end S₄ of the switch element Q4. When the input signal 112 is sent to the control end G₃ of the switch element Q3, a current 204 flows from the input end B to the control end G₃ of the switch element Q3, so that the accumulated charge at the control end G₃ of the switch element Q3 is more than or equal to a total gate charge (Qg) of the switch element Q3. At this time, the switch element Q3 is turned on. When the switch element Q3 is turned on, the input signal 112 may be sent to the control end G₂ of the switch element Q2 through the first end D₃ and the second end S₃ of the switch element Q3.

When the input signal 112 is sent to the control end G₂ of the switch element Q2, a current 206 flows from the input end B to the control end G₂ of the switch element Q2, so that the accumulated charge at the control end G₂ of the switch element Q2 is more than or equal to a total gate charge (Qg) of the switch element Q2. At this time, the switch element Q2 is turned on. When the switch element Q2 is turned on, the input signal 112 may be sent to the control end G₁ of the switch element Q1 through the first end D₂ and the second end S₂ of the switch element Q2. When the input signal 112 is sent to the control end G₁ of the switch element Q1, a current 208 flows from the input end B to the control end G₁ of the switch element Q1, so that the accumulated charge at the control end G₁ of the switch element Q1 is more than or equal to a total gate charge (Qg) of the switch element Q1. At this time, the switch element Q1 is turned on, a current 200 flows from the power voltage A through the first end D₁ and the second end S₁ of the switch element Q1, and finally flows to the ground voltage C, so that the input signal 112 is amplified by the switch element Q1.

In some embodiments, the switch elements Q1, Q2, Q3, Q4, . . . , Qn+1 are MOSFETs, but the present application is not limited thereto. In some embodiments, the switch elements Q1, Q2, Q3, Q4, . . . , Qn+1 may be normally-on switch elements made of any material, such as silicon, silicon carbide, gallium nitride, etc. The switch element Q1 is a main switch element (i.e., the power amplifier 102 in FIG. 1), and the remaining switch elements Q2, Q3, . . . , Qn+1 are secondary switch elements of the present application (i.e., the driving circuit 106 in FIG. 1). In some embodiments, the resistance values of the resistor R1 and the resistor R2 may be customized to any value or 0.

The voltage of the divided voltage signal 114 (for example, the voltage V_{D}) is input to the gate of the switch element Qn+1 to activate the switch element Qn+1. After the switch element Qn+1 is activated, the switch element Qn, the switch element Qn−1, . . . , the switch element Q2, and the switch element Q1 are activated in sequence, so that the final voltage V_{D} may be regarded as the voltage used to activate the switch element Q1.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
an input end, configured to receive an input signal;
a power amplifier, electrically connected between a power voltage and a ground voltage, comprising a first control end;
a voltage dividing circuit, configured to divide the input signal and output a divided voltage signal; and
a driving circuit, comprising a second control end, electrically connected to the voltage dividing circuit through the second control end, and electrically connected to the first control end of the power amplifier; wherein the driving circuit is electrically connected to the input end through a bus to receive the input signal,
wherein the driving circuit outputs the input signal to the power amplifier according to a voltage of the divided voltage signal to drive the power amplifier.

2. The electronic device as claimed in claim 1, wherein the voltage dividing circuit comprises a first resistor and a second resistor; the first resistor is electrically connected between the second resistor and the input end; and the second resistor is electrically connected between the first resistor and the ground voltage.

3. The electronic device as claimed in claim 2, wherein the driving circuit comprises a first switch element; the first switch element comprises a first end, a second end, and a control end; the first end is electrically connected to the input end, the second end is electrically connected to the first control end of the power amplifier, and the control end is electrically connected between the first resistor and the second resistor.

4. The electronic device as claimed in claim 2, wherein the driving circuit comprises a first switch element and a second switch element; the first switch element comprises a first end, a second end, and a control end; and the second switch element comprises a first end, a second end, and a control end.

5. The electronic device as claimed in claim 4, wherein the first end of the first switch element is electrically connected to the input end, the second end of the first switch element is electrically connected to the control end of the second switch element, and the control end of the first switch element is electrically connected between the first transistor and the second transistor.

6. The electronic device as claimed in claim 5, wherein the first end of the second switch element is electrically connected to the input end, and the second end of the second switch element is electrically connected to the first control end of the power amplifier.

7. The electronic device as claimed in claim 3, wherein when the voltage of the divided voltage signal is higher than a threshold voltage of the first switch element, the first switch element outputs the input signal to the power amplifier through its second end.

8. The electronic device as claimed in claim 4, wherein when the voltage of the divided voltage signal is higher than a threshold voltage of the first switch element, the first switch element outputs the input signal to the second switch element through its second end, so that the second switch element outputs the input signal to the power amplifier through its second end.

9. The electronic device as claimed in claim 1, wherein the power amplifier comprises a switch element; the switch element has a threshold voltage; and the voltage of the divided voltage signal is higher than the threshold voltage.

10. The electronic device as claimed in claim 1, wherein the driving circuit comprises multiple switch elements; the switch elements are electrically connected in series with each other, the first one of the switch elements is electrically connected to the power amplifier, and the last one of the switch elements is electrically connected to the voltage dividing circuit.
